(19) United States
(12) Patent Application Publication
(10) Pub. No.: US 2008/0271627 A1
(43) Pub. Date: Nov. 6, 2008

(54) Lithographic printing press and method for on-press imaging laser sensitive lithographic plate

(76) Inventor: Gary Ganghui Teng, Northborough, MA (US)

Correspondence Address: GARY GANGHUI TENG, 10 KENDALL DR., NORTHBOROUGH, MA, 01532, US

(21) Appl. No.: 12/176,377

(22) Filed: Jul. 20, 2008

Related U.S. Application Data
(63) Continuation-in-part of application No. 11/599,734, filed on Nov. 15, 2006.
Application No. 11/599,734 is a continuation-in-part of application No. 11/057,663, filed on Feb. 14, 2005, now Pat. No. 7,427,465.

(51) Int. Cl. B41F 1/18; G03F 7/20

(52) U.S. Cl. 101/450.1; 430/322

(57) ABSTRACT

A lithographic printing press having a plate cylinder in a covered compartment suitable for on-press imaging and developing a laser sensitive plate is described. The plate cylinder as well as certain other press parts is covered by non-transparent and/or safe-light-passing-only covers so that no or only limited amount of unsafe light passes onto the plate mounted on the plate cylinder during on-press imaging and development. The plate comprises on a substrate a photosensitive layer soluble or dispersible in ink and/or fountain solution and capable of hardening upon exposure to a laser having a wavelength selected from 200 to 1200 nm. The plate is on-press exposed with the laser, developed with ink and/or fountain solution, and then directly prints inked images to the receiving sheets.

### RELATED PATENT APPLICATIONS

This application is a continuation-in-part application of U.S. patent application Ser. No. 11/599,734 filed Nov. 15, 2006 which is a continuation-in-part application of U.S. patent application Ser. No. 11/057,663 filed Feb. 14, 2005.

### FIELD OF THE INVENTION

This invention relates to lithographic printing. More particularly, it relates to lithographic printing press suitable for on-press imaging and developing laser sensitive lithographic printing plate and method of using such press and plate.

### BACKGROUND OF THE INVENTION

Lithographic printing is generally performed on a lithographic printing press using a lithographic printing plate (also called planographic printing plate). Lithographic printing plate (after process) generally consists of ink-receptive areas (image areas) and ink-repelling areas (non-image areas); the image areas and the non-image areas are substantially on the same plane. During printing operation, ink is preferentially received in the image areas, not in the non-image areas, and then transferred, usually through a printing blanket, to the surface of a material upon which the image is to be produced.

Lithographic printing plates (processed) are generally prepared from lithographic printing plate precursors (also commonly called lithographic printing plates) comprising a substrate and a photosensitive coating deposited on the substrate, the substrate and the photosensitive coating having opposite surface properties. The photosensitive coating is usually a photosensitive material, which solubilizes or hardens upon exposure to an actinic radiation, optionally with further post-exposure overall treatment. In positive-working systems, the exposed areas become more soluble and can be developed to reveal the underneath substrate. In negative-working systems, the exposed areas become hardened and the non-exposed areas can be developed to reveal the underneath substrate.

The exposed plate is usually developed with a liquid developer to bare the substrate in the non-hardened or solubilized areas. On-press developable lithographic printing plates have been disclosed in the literature. Such plates can be directly mounted on press after exposure to develop with ink and/or fountain solution during the initial prints and then to print out regular printed sheets. No separate development process before mounting on press is needed. Among the patents describing on-press developable lithographic printing plates are U.S. Pat. Nos. 5,258,263, 5,516,620, 5,561,029, 5,616,449, 5,677,110, 5,811,220, 6,014,929, 6,071,675, 6,482,571, 6,737,220, 6,994,028, 6,969,575, and 6,949,327.

Laser sources have been increasingly used to imagewise expose a printing plate which is sensitized to a corresponding laser wavelength. This allows the elimination of the photomask film, reducing material, equipment and labor cost. Suitable lasers include infrared lasers (such as laser diode of about 830 nm and NdYAG laser of about 1064 nm), visible lasers (such as frequency-doubled NdYAG laser of about 532 nm, violet laser diode of about 390-430 nm), and ultraviolet laser (such as ultraviolet laser diode of about 350 to 370 nm). Among them, infrared laser diode, violet laser diode, and ultraviolet laser diode are most attractive. Infrared laser sensitive plates have the advantage of relative white or yellow light stability, violet laser sensitive plates have the advantage of low imager cost due to the low cost of the violet laser diode which is made in mass production for DVD, and ultraviolet laser sensitive plates have the advantage of higher sensitivity (requiring less laser dosage) than longer wavelength lasers.

Laser sensitive plates generally have higher sensitivity (than conventional film based plate) because of the limited laser power and the desire for fast imaging speed. Accordingly, photosensitive plates designed for laser imaging generally have limited room light stability. For example, before being developed to remove the non-hardened areas, frequency-doubled NdYAG laser sensitive plates usually require red room light for handling, violet laser sensitive plates usually require orange or yellow room light for handling, and infrared laser sensitive photopolymer plates usually require yellow room light for handling and have only limited white light stability (due to the use of certain initiator which has spectral sensitivity in the ultraviolet region).

Such limited room light stability is an inherent barrier for the design and use of on-press developable laser sensitive lithographic plate because the pressrooms are generally equipped with white lights, in addition to the difficulties in designing any on-press developable plate with good press performance. Despite of such difficulties, there is a strong desire to develop a high speed laser sensitive on-press developable lithographic plate as well as methods of using it because of its environmental and economic benefits.

Lithographic printing presses installed with a laser exposure device have recently been proposed in the patent literature. Examples include U.S. Pat. Nos. 6,543,348, 6,737,220, and 6,539,859, and U.S. Pat. App. Pub. No. 2003/0081106. Infrared laser is generally used to expose the plate mounted on press according to digital imaging information. Like conventional presses, these presses with laser imager are not designed to be light-tight so that the plate mounted on the plate cylinder sees the room light. Such presses are suitable for on-press imaging and developing infrared laser sensitive plate that has low or no sensitivity to the office white light. However, such presses are not suitable for on-press imaging and developing high speed infrared laser sensitive plate that has high sensitivity to the office white light. Furthermore, such presses, even if installed with a violet or ultraviolet laser, are not suitable for on-press imaging and developing a violet or ultraviolet plate under regular room light because of the very high white light sensitivity of such plate. Even for infrared laser sensitive plate with low sensitivity to white light comprising infrared absorbing dye, the infrared absorbing dye can often be gradually decomposed under white light, causing background toning and/or reduced photospeed after prolonged exposure to white light.

It would be desirable if an on-press imaging lithographic press and method can be developed which allows the convenient use of laser sensitive on-press developable plate on such press under white office light.

### SUMMARY OF THE INVENTION

According to the present invention, there has been provided a lithographic printing press, comprising:
(a) a plate cylinder;
(b) an exposure means capable of emitting a laser with a wavelength selected from 200 to 1200 nm to imagewise expose a lithographic printing plate mounted on said cylinder; and
(c) an inking means comprising an inking unit or both an inking unit and a fountain unit;
(d) wherein at least said plate cylinder as well as the plate mounted on it is within a compartment shielded with covers and other press parts so that no or less than 10% of the room light with wavelength of less than 450 nm reaches the plate mounted on the plate cylinder.

The above plate cylinder is preferably mounted with a lithographic printing plate comprising on a substrate a photosensitive layer soluble or dispersible in ink and/or fountain solution and capable of hardening upon exposure to said laser at the beginning of a printing operation.

According to another aspect of the present invention, there has been provided a method of lithographically printing images on a receiving medium, comprising in order:
(a) providing a lithographic printing press comprising (i) a plate cylinder (ii) an exposure means capable of emitting a laser having a wavelength selected from 200 to 1200 nm, and (iii) an inking means comprising an inking unit or both an inking unit and a fountain unit;
(b) mounting onto said plate cylinder a lithographic printing plate comprising on a substrate a photosensitive layer soluble or dispersible in ink and/or fountain solution and capable of hardening upon exposure to said laser;
(c) imagewise exposing said plate with said laser to cause hardening of the photosensitive layer in the exposed areas; and
(d) applying ink and/or fountain solution from said inking means to said plate to remove the non-hardened areas of said photosensitive layer and to print images from said plate to the receiving medium;
(e) wherein at least said plate mounted on the plate cylinder is within a compartment shielded with covers and other press parts so that no or less than 10% of the room light with wavelength shorter than 450 nm reaches the plate.

The term “the room light with wavelength shorter than 450 nm” means the below-450 nm portion of the room light. The term “less than 10% of the room light with a wavelength shorter than 450 nm reaches the plate” means the intensity for light coming from outside of the press at each wavelength below 450 nm around the plate cylinder is less than 10% of the intensity of the light at such wavelength around outer top surface of the press under normal office lighting (with light coming from the ceiling lamps); in other words when there is no light source (if any) turned on within the compartment, the intensity of the light at each wavelength below 450 nm around the plate cylinder is less than 10% of the intensity of the light at such wavelength around the outer top surface of the press. The compartment can be in darkness or substantially darkness, or have yellow or red light coming through the yellow or red transparent covers from the room light. Preferably less than 1%, more preferably less than 0.2% and most preferably none, of the room light or of the portion of the room light with wavelengths below 450 nm reaches the plate cylinder; in other words, when there is no light source (if any) turned on within the compartment, the intensity of the light at each wavelength below 450 nm around the plate cylinder is preferably less than 1% and more preferably less than 0.2% of the intensity of the light at such wavelength around the outer top surface of the press, and is most preferably zero. Preferably, the press is in a pressroom having white room light.

The covers together with other press parts prevent all or at least 90% of the room light or of the portion of the room light having wavelengths below 450 nm from reaching the plate mounted on the plate cylinder to cause undesired photo reaction of the photosensitive layer of the plate. The covers and other press parts can be non-transparent to light or only transparent to light with wavelength above 450 nm, preferably above 500 nm, most preferably above 550 nm. Preferably, the covers have some areas non-transparent to any room light and some other areas only transparent to yellow or red light. The compartment can cover (i) the plate cylinder, part of the exposure means, and part of the inking means; (ii) the plate cylinder, the exposure means, and part of the inking means; (iii) the plate cylinder, the exposure means, and the inking means; (iv) the plate cylinder, the blanket cylinder, the impression cylinder, the exposure means, the inking means, the medium to be fed, and the printed medium; or (v) the entire press except for certain controlling handles or buttons; as long as the plate mounted on the plate cylinder is shielded from at least 90% of the room light having wavelength of less than 450 nm and all the press moving parts can move as designed. Preferably, the compartment covers the entire press except for certain control buttons. The compartment can be connected to a light-tight cassette containing the plate to be fed or can have a light-tight slot for feeding a plate from a light-tight cassette or bag or covered with a non-transparent cover sheet, or the plate can be automatically mounted on the surface of the plate cylinder from a roll of fresh plate in a light-tight cartridge stored inside the plate cylinder.

Any laser with a wavelength from 200 to 1200 nm can be used for this instant invention. Preferred lasers are violet or ultraviolet laser (200 to 430 nm) and infrared laser (750 to 1200 nm); more preferred is violet or ultraviolet laser. For plate sensitive to a violet or violet laser (200 to 430 nm), the exposure dosage is preferably less than 2000 μJ/cm² (2 mJ/cm²), more preferably less than 500 μJ/cm², and most preferably less than 200 μJ/cm². For plate sensitive to an infrared laser (750 to 1200 nm), the exposure dosage is preferably less than 2000 mJ/cm², more preferably less than 500 mJ/cm², and most preferably less than 200 mJ/cm².

### BRIEF DESCRIPTION OF THE DRAWINGS

FIG. 1 is a diagrammatic cross-sectional view of a lithographic printing press of the invention having a fully covered compartment for the plate cylinder and other parts, which compartment is fully or substantially fully blocked from the room light or the unsafe portion of the room light.

FIG. 2 is a diagrammatic cross-sectional view of a lithographic printing press of the invention wherein the light-tight compartment has a light-tight slot on the cover to allow the entrance of the plate without letting light enter the compartment.

FIG. 3 is a diagrammatic cross-sectional view of a lithographic printing press of the invention wherein the light-tight compartment covers only part of the press components including the plate cylinder, the exposure means, part of the inking system, and part of the blanket cylinder to ensure that the plate mounted on the plate cylinder is blocked from at least 90% of the room light or of the unsafe portion of the room light.

FIG. 4 is a diagrammatic cross-sectional view of a lithographic printing press of the invention wherein the plate is installed inside the cylinder in the form of roll.

FIG. 5 is a diagrammatic cross-sectional view of a multicolor lithographic printing press of the invention with 4 sets of plate cylinders and blanket cylinders sharing the same impression cylinder.

FIG. 6 is a diagrammatic cross-sectional view of a multicolor lithographic printing press of the invention with 4 single-color printing units lined up in tandem.

FIG. 7 is a diagrammatic cross-sectional view of a multicolor lithographic printing press of the invention with 4 single-color printing units lined up in tandem wherein the medium to be printed is a web instead of sheet.

### DETAILED DESCRIPTION OF THE PREFERRED EMBODIMENTS

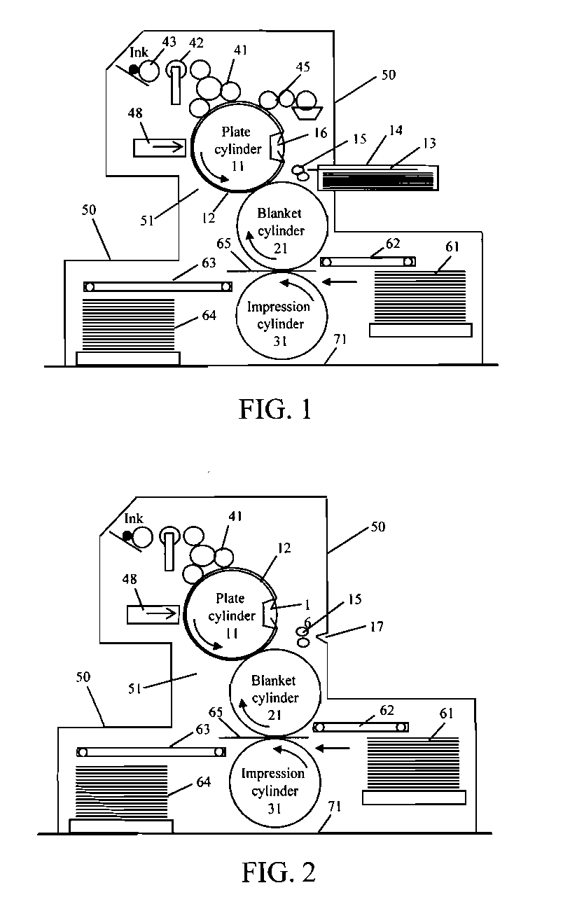

Any lithographic printing presses having at least one plate cylinder, including all current commercial lithographic presses and the lithographic presses described in the patent literature, can be modified into the printing press of the current invention by adding covers to block off all or at least 90% (preferably at least 99%, more preferably at least 99.8%, and most preferably all) of the room light or of the unsafe portion of the room light (such as with wavelength below 450 nm) from reaching the plate cylinder and by adding a laser exposure means. Preferably, at least 90% (preferably at least 99%, more preferably at least 99.8%, and most preferably all) of the unsafe portion of the room light is prevented from reaching the plate. The lithographic press of the instant invention can be designed in various ways, using any of the current lithographic press designs and any design and arrangement of covers to block off all or at least 90% of the unsafe light from entering the compartment containing the plate cylinder without hindering the designed motions or rotations of the moving parts of the press. Portion of the covers can be opened after on-press imaging and development to allow easy viewing or adjustment inside the press, such as adjusting the ink or fountain unit, adjusting the plate, or handling the paper. Some of the preferred designs of the lithographic press of the instant invention are illustrated in FIGS. 1-7. However, various modifications can be made to achieve the current invention, as long as the lithographic press having a laser exposure means is shielded with covers which prevent all or at least 90% (preferably at least 99%, more preferably at least 99.8%, and most preferably all) of the room light or of the unsafe portion of the room light from reaching the plate cylinder.

Although it is ideal to block off all the room light or unsafe portion of the room light from entering the compartment containing the plate cylinder, small amount of undesired light may leak in, for example, from certain small gaps between various parts and covers, due to the slight transparency to unsafe light of certain cover materials, or due to design limitations. Such small amount of light (less than 10% preferably less than 1% and more preferably less than 0.2% of the room light) is acceptable as long as it does not cause undesirable amount of photo reaction to adversely effect the performance of the particular plate.

As illustrated in FIG. 1, the lithographic printing press of this invention has a fully covered compartment for the plate cylinder and other parts, which compartment is fully or substantially fully blocked from the room light or the unsafe portion of the room light. The printing press comprises a plate cylinder 11 for mounting a printing plate 12, an inking unit 41 for applying ink to the plate 12, a fountain unit 45 for applying fountain solution to the plate 12, a laser exposure means 48 for exposing the plate 12 with a laser according to digital imaging information, a blanket cylinder 21 for receiving the inked imaging from the plate 12 to transfer to the receiving medium 65, an impression cylinder 31 for pressing the receiving medium 65 against the blanket cylinder 21, and a light-tight cassette 14 for supplying and feeding the plate 13 to the plate cylinder 11 without exposing the plate to any light or any unsafe light. The medium to be printed 61 is fed to between the blanket cylinder 21 and the impression cylinder 31 through a feeding means 62, and then transported to the printed medium pile 64 through a transporting means 63. A loading unit 15 picks up the plate from the cassette and transports to the plate cylinder 11. The plate cylinder has an automatic mounting unit 16 that automatically mounts the plate 12 onto the plate cylinder 11. The plate cylinder and other press parts are covered with the covers 50 that block off all or at least 90% of the room light or of the unsafe portion of the room light. The bottom 71 can be the floor of the room or can be part of the press. The duct roller 43 and vibrator 42 transfer ink to the ink rollers and are part of the inking unit. After the plate 12 is imaged and on-press developed, part of the covers can be opened to allow easy viewing or adjustment or better ventilation. The components of the press are generally mounted on an upstanding machine frame (not shown), and all moving parts are capable of moving or rotating as designed. It is noted that the inking unit 41, and fountain unit 45 (if any), are together called inking system or inking means in this application.

In addition to loading the plate from the cassette, the plate can be mounted onto the plate cylinder of the press of FIG. 1 by any means. For example, the plate can be manually mounted on press with a portion of the covers 50 in the open position while under yellow or red room light, and the opened portion of the covers 50 can then be closed and the room light is switched to white light to start laser imaging and on-press development. Also, the plate can be covered with a non-transparent cover sheet, and mounted on the plate cylinder with a portion of the covers 50 in an open position under white room light; the covers can then be fully covered; a peeling device installed near the plate cylinder can be activated to peel off the cover sheet; and the plate is then imaged and on-press developed. Once the plate is on-press developed, some of the covers can be in the open position.

FIG. 2 illustrates a printing press of the instant invention wherein the light-tight compartment 51 has a light-tight slot 17 on the cover to allow the entrance of the plate without letting light entering the compartment 51. The plate can be fed from a light-tight cassette, light-tight bag, or covered with a non-transparent cover sheet. The cassette, bag, or cover sheet can be left outside or inside of the light-tight slot. A peeling device can be installed around the slot to peel off the cover sheet without exposing the photosensitive layer of the plate to the room light. The press as illustrated has an inking unit 41, but does not have fountain unit. Such press is suitable for printing waterless plate that requires ink only or for printing wet plate using single fluid ink. However, this press can be further installed with a fountain unit to print wet plate with regular ink. The plate cylinder and other press parts are covered with the covers 50 which block off all or at least 90% of the room light or of the unsafe portion of the room light.

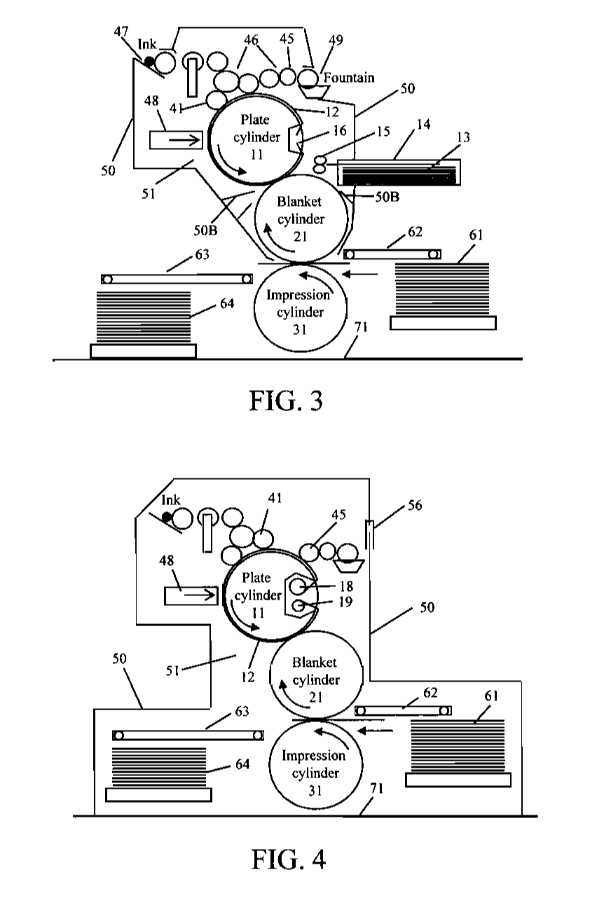

FIG. 3 illustrates a printing press of the instant invention wherein the light-tight compartment 51 covers only part of the press components including the plate cylinder 11, the exposure means 48, part of the inking system 46, and part of the blanket cylinder 21 to ensure that the plate 12 mounted on the plate cylinder 11 is blocked from at least 90% of the room light or of the unsafe portion of the room light. Both the ink reservoir 47 and the fountain reservoir 49 are outside of the compartment to allow ease of adding ink and fountain solution. Several layers of covers 50B are installed closely around the blanket cylinder 21 preferably without touching it to block off most of the room light from entering the compartment. This press employs an integrated inking system 46 wherein the fountain is transferred through fountain rollers 45 to the inking rollers 41 to form emulsion of ink and fountain before applying to the plate 12 mounted on the plate cylinder 11. This integrated inking system is an alternative to a conventional inking system as in FIG. 1 wherein the fountain and ink are separately applied to the plate mounted on the plate cylinder. Both conventional and integrated inking systems are well known and either can be used on a wet press of the instant invention.

FIG. 4 illustrates a printing press of the instant invention wherein the plate is installed inside the cylinder in the form of roll. The plate 12 is pulled out from the original unexposed plate roll 18 to mount onto the plate cylinder 11 and then wound onto the used plate roll 19. The plate in roll 18 is preferably in a light-tight cartridge so that it is not exposed to light even under room light. After the completion of a printing job and before a new printing job, preferably automatically, the printed portion of the plate mounted on the plate cylinder can be wound onto the used plate roll 19 and a fresh portion of the plate can be pulled out from the fresh plate roll 18 to mount on the plate cylinder to start a new laser exposure, on-press development, and printing cycle. A labyrinth 56 that passes air without passing significant amount of light is optionally contained on the covers 50 to allow ventilation.

In addition to having one set of plate rolls on a plate cylinder as in FIG. 4, in certain press designs, the same plate cylinder can have 2 or more sets of plate rolls; each set of plate is mounted on a different part of the cylinder surface along the rotating angle with the respective fresh and used plate rolls installed within the cylinder. Each plate is preferably mounted on the plate cylinder occupying equal amount of cylinder surface areas along the rotating angle of the cylinder, so that the plate cylinder surface is divided into several equal segments along the rotating direction of the cylinder with each plate mounted on one of the segments and the respective rolls installed within the cylinder around the respective segments. Here, the blanket cylinder preferably has the same number of segments as the plate cylinder, with each of the segments corresponding to one of the segments of the plate cylinder and transferring one of the colors from the plate cylinder to the receiving sheets; the impression cylinder is preferably capable of holding each receiving sheet (such as paper) for printing each of the colors from the blanket cylinder before transferring the receiving sheet to the pile of printed receiving sheet, or to the next printing unit (having a plate cylinder, a blanket cylinder, an impression cylinder and an inking means, and preferably having a laser) if there are 2 or more printing unit in a press. This allows having plates for different colors on the same plate cylinder. In one specific embodiment, the same plate cylinder has 2 sets of plates, the first plate is mounted on the plate cylinder surface from about 0° to about 180° of the rotating direction of the cylinder with the corresponding fresh and used plate rolls installed within the cylinder, and the second plate is mounted on the same plate cylinder surface from about 180° to about 360° (0°) of the rotating direction of the cylinder with the corresponding rolls installed within the cylinder. In another specific embodiment, the same plate cylinder has 4 sets of plates, the first plate is mounted on the plate cylinder surface from about 0° to about 90° of the rotating direction of the cylinder with the corresponding fresh and used plate rolls installed within the cylinder, the second plate is mounted on the plate cylinder surface from about 90° to about 180° of the rotating direction of the cylinder with the corresponding rolls installed within the cylinder, the third plate is mounted on the plate cylinder surface from about 180° to about 270° of the rotating direction of the cylinder with the corresponding rolls installed within the cylinder, the fourth plate is mounted on the plate cylinder surface from about 270° to about 360° (0°) of the rotating direction of the cylinder with the corresponding rolls installed within the cylinder. In yet another specific embodiment, the same plate cylinder has n sets of plates, where n is any whole number, preferably n is 1, 2, 3, 4, 5, 6, 7, or 8, and more preferably n is 2, 3, 4, 5, or 6; the first plate is mounted on the plate cylinder surface from about 0° to about 360/n° of the rotating direction of the cylinder with the corresponding fresh and used plate rolls installed within the cylinder; if there are 2 or more plates, the second plate is mounted on the plate cylinder surface from about 360/n° to about 2×360/n° of the rotating direction of the cylinder with the corresponding rolls installed within the cylinder; if there are 3 or more plates, the third plate is mounted on the plate cylinder surface from about 2×360/n° to about 3×360/n° of the rotating direction of the cylinder with the corresponding rolls installed within the cylinder, . . . the nth plate is mounted on the plate cylinder surface from about (n−1)×360/n° to about n×360/n° (0°) of the rotating direction of the cylinder with the corresponding rolls installed within the cylinder.

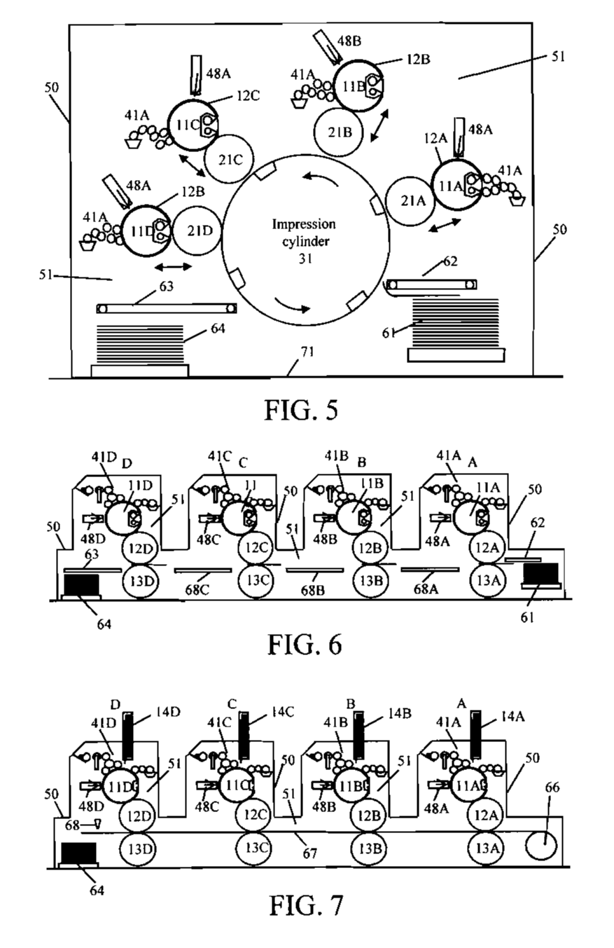

FIG. 5 illustrates a multicolor press with 4 sets of plate cylinders 11A-D and blanket cylinders 21A-D sharing the same impression cylinder 31. The plates in the form of roll are installed inside the cylinders and automatically pulled out from the rolls to mount on the plate cylinders for each new printing job. All the plate cylinders and other press parts are covered with the covers 50 that block off all or at least 90% of all light or unsafe light.

FIG. 6 illustrates a multicolor press with 4 single-color printing units A-D lined up in tandem. The medium to be printed 61 is printed first on printing unit A with the first color, further passes through printing unit B to be printed for the second color, further passes through printing unit C to be printed for the third color, further passes through printing unit D to be printed for the fourth color, and then collected onto the pile of printed medium 64. All the plate cylinders and other press parts are covered with the covers 50 which block off all or at least 90% of the room light or of the unsafe portion of the room light.

FIG. 7 illustrates a multicolor press with 4 single-color printing units A-D lined up in tandem. The medium to be printed is a web instead of sheet. It is unwound from the roll of fresh medium (typically paper) 66, passes through the 4 printing units to be printed with 4 different colors, cut into sheets with cutter 68, and then collected onto the pile of printed medium 64. All the plate cylinders and other press parts are covered with the covers 50 which block off all or at least 90% of the room light or of the unsafe portion of the room light.

The covers can be all non-transparent to all room light, all transparent to safe light only, or non-transparent to any room light in certain parts and transparent to safe light only in other parts. Preferably, the covers are non-transparent in certain parts and only transparent to safe light in other parts. The lithographic press of this invention preferably has a portion of the covers being only transparent to light of above 450 nm, more preferably above 500 nm, and most preferably above 550 nm, with the rest of the covers being non-transparent. Such a press allows viewing of the plate cylinder and other internal parts through a yellow or red window (as part of the covers). Some of the covers for the press can be opened after the plate has been on-press imaged and developed, to allow ease of viewing, adjustment and ventilation. An interlocking mechanism can be designed so that all the covers are closed during plate mounting, imaging and on-press development.

A small pipe can be connected between the inside and outside of the compartment to allow ventilation. The pipe can be curved many times and preferably have dark internal surface so that no or substantially no light passes into the compartment through the pipe. Small opening on the covers with objects to block off the direct light, preferably in areas of the covers far from the plate cylinder, can be made to allow ventilation. Such opening is also called labyrinth, which allows air to pass through without passing significant amount of light. In any event, only less than 10% (preferably less than 1%, more preferably less than 0.2%, and most preferably none) of the room light or unsafe portion of the room light reaches the plate cylinder.

A safe light source, such as a yellow or red lamp, which can be turned on or off, can be installed inside the compartment to facilitate viewing inside the compartment during plate mounting, imaging, and/or on-press development. For press having at least a portion of the covers being transparent to a safe light (such as a yellow or red light) only, such a safelight source (preferably a yellow or red light lamp) can be advantageously installed within the compartment. Of course, a white light source can also be installed inside the compartment, but can not be turned on until the plate has been imaged and on-press developed.

The lithographic plate can be supplied as sheet or roll in a light-tight state, such as in a cartridge or cassette or covered with a non-transparent cover sheet, and is preferably automatically loaded onto the plate cylinder. The light-tight cartridge or cassette is non-transparent to any room light or only transparent to safe light (such as with wavelengths above 450 nm, preferably above 500 nm, and most preferably above 550 nm). Preferably, the light-tight cartridge or cassette is non-transparent to any room light.

In this patent, the term yellow or red light means a visible light having wavelengths above at least 450 nm, preferably above 500 nm, and more preferably above 550 nm; including any yellow light, red light, or any light with color between red and yellow, such as from an incandescence or fluorescence lamp with a yellow or red cap. The term safe light means a yellow or red light. The term unsafe light or unsafe portion of the room light is defined as light with wavelength below 450 nm. The term room light includes any light in a typical office, such as white fluorescence light, white incandescence light, and sunlight (coming from the windows to the pressroom). The term light-tight means no light or no light with wavelengths below 450 nm can pass through; preferably no light can pass through.

The substrate employed in the lithographic plates of this invention can be any lithographic support. Such a substrate can be a metal sheet, a polymer film, or a coated paper. Aluminum (including aluminum alloy) sheet is a preferred metal support. Particularly preferred is an aluminum support that has been grained and anodized (with or without deposition of a barrier layer). Polyester film is a preferred polymeric film support. A surface coating may be coated to achieve desired surface properties. For wet plate, the substrate should have a hydrophilic or oleophilic surface, depending on the surface properties of the photosensitive layer; commonly, a wet lithographic plate has a hydrophilic substrate and an oleophilic photosensitive layer. For waterless plate, the substrate should have an oleophilic or oleophobic surface, depending on the surface properties of the photosensitive layer.

Particularly suitable hydrophilic substrate for a wet lithographic plate is an aluminum support that has been grained and anodized; such a substrate is preferably further deposited with a hydrophilic barrier layer. Surface graining (or roughening) can be achieved by mechanical graining or brushing, chemical etching, and/or AC electrochemical graining. The roughened surface can be further anodized to form a durable aluminum oxide surface using an acid electrolyte such as sulfuric acid and/or phosphoric acid. The roughened and anodized aluminum surface can be further thermally or electrochemically coated with a layer of silicate or hydrophilic polymer such as polyvinyl phosphonic acid, polyacrylamide, polyacrylic acid, polybasic organic acid, copolymers of vinyl phosphonic acid and acrylamide to form a durable hydrophilic layer. Polyvinyl phosphonic acid and its copolymers are preferred polymers. Processes for coating a hydrophilic barrier layer on aluminum in lithographic plate application are well known in the art, and examples can be found in U.S. Pat. Nos. 2,714,066, 4,153,461, 4,399,021, and 5,368,974. Suitable polymer film supports for a wet lithographic plate include a polymer film coated with a hydrophilic layer, preferably a hydrophilic layer that is crosslinked, as described in U.S. Pat. No. 5,922,502.

For preparing lithographic printing plates of the current invention, any photosensitive layer is suitable which is capable of hardening upon exposure to a laser having a wavelength selected from 200 to 1200 nm, and is soluble or dispersible in ink (for waterless plate) or in ink and/or fountain solution (for wet plate). Here hardening means becoming insoluble and non-dispersible in ink and/or fountain solution. In this invention, hardening can be achieved through any means, including chemical reactions (such as polymerization, crosslinking, and chemical changes of monomer, polymer or compound) and physical changes (such as coalescence of polymer particles). Preferably, hardening is achieved through chemical reaction (such as polymerization, crosslinking, or chemical change). More preferably, hardening is achieved through crosslinking or polymerization of the resins (polymers or monomers). Most preferably, hardening is achieved through polymerization of the monomers. A laser sensitive dye or pigment is usually used in the photosensitive layer. The photosensitive layer preferably has a coverage of from 100 to 4000 mg/m², and more preferably from 400 to 2000 mg/m².

Photosensitive layer suitable for the current invention may be formulated from various photosensitive materials, usually with addition of a sensitizing dye or pigment. The composition ratios (such as monomer to polymer ratio) are usually different from conventional plates designed for development with a regular liquid developer. Various additives may be added to, for example, allow or enhance on-press developability. Such additives include surfactant, plasticizer, water soluble polymer or small molecule, and ink soluble polymer or small molecule. The addition of nonionic surfactant is especially helpful in making the photosensitive layer dispersible with ink and fountain solution, or emulsion of ink and fountain solution. Various additives useful for conventional photosensitive layer can also be used. These additives include pigment, dye, exposure indicator, and stabilizer.

In this patent, the term monomer includes both monomer and oligomer, and the term (meth)acrylate includes both acrylate and methacrylate (A monomer means a monomer or an oligomer, and a (meth)acrylate monomer means an acrylate monomer, a methacrylate monomer, or a monomer with both acrylate and methacrylate groups.). The term monomer to polymer weight ratio means the weight ratio of all the specific monomers to all the polymeric binders (which are solid film-forming polymers); liquid polymer such as nonionic surfactant is not considered polymeric binder and is not included in the monomer to polymer weight ratio calculation. The term “comprises a . . . ” means “comprises at least one . . . ”; for example, the term “comprising a monomer” means “comprising at least one monomer.”

Photosensitive materials useful in wet plates of this invention include, for example, photosensitive compositions comprising a polymerizable monomer, an initiator, a sensitizing dye, and optionally a polymer.

Photosensitive oleophobic materials useful in waterless plates of this invention include, for example, compositions comprising a monomer having perfluoroalkyl or polysiloxane groups and crosslinkable terminal groups, an initiator, and a sensitizing dye.

Infrared laser sensitive (thermosensitive) materials useful for wet lithographic plates of this invention include, for example, thermosensitive compositions comprising a polymerizable monomer, an initiator, an infrared light absorbing dye, and optionally a polymer. Also useful thermosensitive materials are infrared sensitive compositions comprising a crosslinkable polymer and an infrared absorbing dye or pigment. Further useful thermosensitive materials are infrared sensitive compositions comprising a polymer or compound capable of becoming insoluble upon heat and an infrared absorbing dye or pigment. Yet further useful thermosensitive materials are infrared sensitive compositions comprising a polymeric particulate dispersion and an infrared absorbing dye or pigment.

Visible or ultraviolet laser sensitive materials useful for wet plates of this invention include, for example, photosensitive compositions comprising a polymerizable monomer, an initiator, a visible or ultraviolet light sensitizing dye, and optionally a polymer. Also useful visible or ultraviolet laser sensitive materials are photosensitive materials comprising a crosslinkable or polymerizable polymeric binder and a visible or ultraviolet laser sensitizing dye, preferably with addition of an initiator.

Violet or ultraviolet laser sensitive materials useful as photosensitive layer of this invention include, for example, photosensitive compositions comprising a polymerizable monomer, an initiator, a violet or ultraviolet sensitizing dye, and optionally a polymeric binder; a hydrogen donor is preferably added to accelerate the polymerization. Also useful violet or ultraviolet laser sensitive materials are photosensitive materials comprising a crosslinkable or polymerizable polymeric binder and a violet or ultraviolet laser sensitizing dye, preferably with addition of an initiator.

Polymeric binder for the photosensitive layer of this invention can be any solid film-forming polymer. The polymer may or may not have (meth)acrylate groups or other ethylenic groups (such as allyl groups). Examples of suitable polymeric binders include (meth)acrylic polymers and copolymers (such as polybutylmethacrylate, polyethylmethacrylate, polymethylmethacrylate, polymethylacrylate, butylmethacrylate/methylmethacrylate copolymer, methylmethacrylate/methylmethacrylic acid copolymer, polyallylmethacrylate, and allylmethacrylate/methacrylic acid copolymer), polyvinyl acetate, polyvinyl butyrate, polyvinyl chloride, styrene/acrylonitrile copolymer, styrene/maleic anhydride copolymer and its partial ester, nitrocellulose, cellulose acetate butyrate, cellulose acetate propionate, vinyl chloride/vinyl acetate copolymer, butadiene/acrylonitrile copolymer, and polyurethane binder. Examples of suitable polymers having ethylenic groups include polymers containing (meth)acrylate groups or allyl groups. Polymers having acetoacetate groups, including, for example, the acetoacetylated polymers as described in U.S. Pat. Nos. 6,919,416 and 7,001,958, can also be used as the polymeric binder in the photosensitive layer of this invention. The polymeric binder suitable for the photosensitive layer of this invention has a weight average molecular weight of at least 5,000, preferably from 10,000 to 1,000,000, more preferably from 20,000 to 500,000, and most preferably from 50,000 to 200,000 Dalton. It is noted that polymeric compounds with weight average molecular weight of less that 5,000 can also be added in the photosensitive layer of this invention; however, in order to avoid confusion, such compounds are not considered as polymeric binder and are called oligomer (without or with ethylenic groups) in this application (oligomers having ethylenic groups are also included in the definition of monomers in this application).

Suitable free-radical polymerizable monomers (including oligomers) for the instant invention include, for example, multifunctional (meth)acrylate monomers or oligomers, such as (meth)acrylate esters of ethylene glycol, trimethylolpropane, pentaerythritol, ethoxylated ethylene glycol and ethoxylated trimethylolpropane; multifunctional urethanated (meth)acrylate; multifunctional epoxylated (meth)acrylate; oligomeric amine diacrylates; and reaction products of a compound having at least one acetoacetate group and a multifunctional (meth)acrylate compound. The monomers can be urethane (meth)acrylate, or non-urethane (meth)acrylate. Combination of both urethane (meth)acrylate and non-urethane (meth)acrylate monomers can be used. Here, urethane (meth)acrylate monomers include any compounds having at least one urethane linkage (—NHCOO—) and at least one (meth)acrylate group; and non-urethane (meth)acrylate monomers include any (meth)acrylate monomers without urethane linkage (—NHCOO—) in the molecule. The monomer for the photosensitive layer of this invention preferably has at least 3 (meth)acrylate groups, more preferably at least 4 (meth)acrylate groups, even more preferably at least 5 (meth)acrylate groups, and most preferably at least 6 (meth)acrylate groups. However, monofunctional or difunctional (meth)acrylate monomer can be added into the photosensitive layer having multifunctional (meth)acrylate monomers, the total amount of such monofunctional or difunctional monomers is preferably less than 50% by weight of the total monomers, more preferably less than 30%, and most preferably less than 10%. Acrylate monomer is preferred over methacrylate monomer because of the faster photospeed of acrylate group over methacrylate group. The monomer has a molecular weight of less than 5,000, preferably from 100 to 3,000, more preferably from 200 to 2,000, and most preferably from 300 to 1,500 Dalton.

The free radical initiators useful for the photosensitive layer of this invention include any initiators capable of generating free radicals or other activating species to cause polymerization of the monomers upon exposure to a laser having a wavelength selected from 200 to 1200 nm, with or without the presence of a sensitizing dye. Suitable free-radical initiators include, for example, onium salts such as diaryliodonium hexafluoroantimonate, diaryliodonium hexafluorophosphate, diaryliodonium triflate, (4-(2-hydroxytetradecyl-oxy)phenyl)phenyliodonium hexafluoroantimonate, (4-octoxyphenyl)phenyliodonium hexafluoroantimonate, bis(4-t-butylphenyl)iodonium hexafluorophosphate, triarylsulfonium hexafluorophosphate, triarylsulfonium p-toluenesulfonate, (3-phenylpropan-2-onyl) triaryl phosphonium hexafluoroantimonate and N-ethoxy(2-methyl)pyridinium hexafluorophosphate, and the onium salts as described in U.S. Pat. Nos. 5,955,238, 6,037,098 and 5,629,354; borate salts such as tetrabutylammonium triphenyl(n-butyl)borate, tetraethylammonium triphenyl(n-butyl)borate, diphenyliodonium tetraphenylborate, and triphenylsulfonium triphenyl(n-butyl)borate, and the borate salts as described in U.S. Pat. Nos. 6,232,038 and 6,218,076; haloalkyl substituted s-triazines such as 2,4-bis(trichloromethyl)-6-(p-methoxy-styryl)-s-triazine, 2,4-bis(trichloromethyl)-6-(4-methoxy-naphth-1-yl)-s-triazine, 2,4-bis(trichloromethyl)-6-piperonyl-s-triazine, and 2,4-bis(trichloromethyl)-6-[(4-ethoxyethylenoxy)-phen-1-yl]-s-triazine, and the s-triazines as described in U.S. Pat. Nos. 5,955,238, 6,037,098, 6,010,824, and 5,629,354; hexaarylbiimidazole compounds such as 2,2′-bis(2-chlorophenyl)4,4′,5,5′-tetraphenyl-1,1′-biimidazole, 2,2′-bis(2-ethoxyphenyl)-4,4′,5,5′-tetraphenyl-1,1′-biimidazole, and 2-(1-naphthyl)-4,5-diphenyl-1,2′-biimidazole; and titanocene compounds such as bis(η°-2,4-cyclopentadien-1-yl) bis[2,6-difluoro-3-(1H-pyrrol-1-yl)phenyl) titanium. For thermosensitive plate, onium salts, borate salts, and s-triazines are preferred free radical initiators; onium salts and borate salts are more preferred; and onium salts (particulary diaryliodonium salts and triarylsulfonium salts) are most preferred. For violet or ultraviolet plate, hexaarylbiimidazole compounds and titanocene compounds are preferred free radical initiators, and hexaarylbiimidazole compounds are more preferred. One or more initiators can be added in a photosensitive layer. The initiator is added in the photosensitive layer preferably at 0.5 to 40% by weight of the photosensitive layer, more preferably at 2 to 30%, and most preferably at 5 to 20%.

Suitable polyfunctional epoxy monomers include, for example, 3,4-epoxycyclohexylmethyl-3,4-epoxycyclohexane carboxylate, bis-(3,4-epoxycyclohexylmethyl) adipate, difunctional bisphenol A/epichlorohydrin epoxy resin and multifunctional epichlorohydrin/tetraphenylol ethane epoxy resin.

Suitable cationic initiators include, for example, triarylsulfonium hexafluoroantimonate, triarylsulfonium hexafluorophosphate, diaryliodonium hexafluoroantimonate, and haloalkyl substituted s-triazine. It is noted that most cationic initiators are also free radical initiators because, in addition to generating Bronsted acid, they also generate free radicals during photo or thermal decomposition.

Infrared absorbers useful in the thermosensitive layer of this invention include any infrared absorbing dye or pigment effectively absorbing an infrared radiation having a wavelength of 700 to 1,500 nm. It is preferable that the dye or pigment having an absorption maximum between the wavelengths of 750 and 1,200 nm. Various infrared absorbing dyes or pigments are described in U.S. Pat. Nos. 5,858,604, 5,922,502, 6,022,668, 5,705,309, 6,017,677, and 5,677,106. and in the book entitled “Infrared Absorbing Dyes” edited by Masaru Matsuoka, Plenum Press, New York (1990), and can be used in the thermosensitive layer of this invention. Examples of useful infrared absorbing dyes include squarylium, croconate, cyanine (including polymethine), phthalocyanine (including naphthalocyanine), merocyanine, chalcogenopyryloarylidene, oxyindolizine, quinoid, indolizine, pyrylium and metal dithiolene dyes. Cyanine and phthalocyanine dyes are preferred infrared absorbing dyes. Examples of useful infrared absorbing pigments include black pigments, metal powder pigments, phthalocyanine pigments, and carbon black. Carbon black is a preferred infrared absorbing pigment. Mixtures of dyes, pigments, or both can also be used. Infrared absorbing dye is preferred over infrared absorbing pigment because the infrared absorbing dye usually has higher absorbing efficiency, gives less visible color, and allows molecular level charge or energy transfer to activate the initiator. The infrared dye or pigment is added in the thermosensitive layer preferably at 0.01 to 30% by weight of the thermosensitive layer, more preferably at 0.1 to 20%, and most preferably at 0.5 to 10%.

Visible or ultraviolet sensitizing dyes useful in the visible or ultraviolet sensitive photosensitive layer of this invention include any dyes having a wavelength maximum of from 200 to 600 nm and capable of directly or indirectly causing polymerization of the monomers upon exposure to the corresponding laser. Usually, the visible or ultraviolet dye activates an initiator to cause the polymerization of the monomer upon exposure to a laser. Suitable visible and ultraviolet sensitive dyes include, for example, cyanine dyes (including polymethine dyes); rhodamine compounds such as rhodamine 6G perchloride; chromanone compounds such as 4-diethylaminobenzilidene chromanone; dialkylaminobenzene compounds such as ethyl 4-dimethylaminobenzoate and dialkylaminobenzene; dialkylaminobenzophenone compounds such as 4,4′-bis(dimethylamino)benzophenone, 4,4′-bis(diethylamino)benzophenone, 2-(p-dimethylaminophenyl)benzooxazole, 2-(p-diethylaminophenyl)benzooxazole, 2-(p-dimethylaminophenyl)benzo[4,5]benzooxazole, 2-(p-dimethylaminophenyl)benzo[6,7]benzooxazole, 2,5-bis(p-diethylaminophenyl)1,3,4-oxazole, 2-p-dimethylaminophenyl)benzothiazole, 2-(p-diethylaminophenyl)benzothiazole, 2-(p-dimethylaminophenyl)benzimidazole, 2-(p-diethylaminophenyl)benzimidazole, 2,5-bis(p-diethylaminophenyl)1,3,4-thiadiazole, (p-dimethylaminophenyl)pyridine, (p-diethylaminophenyl)pyridine, 2-(p-dimethylaminophenyl)quinoline, 2-p-diethylaminophenyl)quinoline, 2-(p-dimethylaminophenyl)pyrimidine or 2-(p-diethylaminophenyl)pyrimidine; unsaturated cyclopentanone compounds such as 2,5-bis{[4-(diethylamino)phenyl]methylene}-(2E,5E)-(9Cl)-cyclopentanone and bis(methylindolenyl)cyclopentanone; coumarin compounds such as 3-benzoyl-7-methoxy coumarin and 7-methoxy coumarin; and thioxanthene compounds such as 2-isopropylthioxanthenone. Dialkylaminobenzene compounds and bis(dialkylamino)benzophenone compounds are particularly suitable for ultraviolet laser sensitive plate. Bis(dialkylamino)benzophenone compounds are particularly suitable for violet laser sensitive plate. The sensitizing dyes as described in U.S. Pat. Nos. 5,422,204 and 6,689,537, and U.S. Pat. App. Pub. No. 2003/0186165 can be used for the photosensitive layer of this invention. The visible or ultraviolet sensitizing dye is added in the photosensitive layer preferably at 0.1 to 20% by weight of the photosensitive layer, more preferably 0.5 to 15%, and most preferably 1 to 10%.

The photosensitive layer of the present invention may contain one or more hydrogen donors as a polymerization accelerator. Preferred hydrogen donors are compounds having a mercapto group (also called mercapto compounds), such as 2-mercaptobenzoxazole, 2-mercaptobenzothiazole, 2-mercaptobenzimidazole and 3-mercapto-1,2,4-triazole; and N-aryl-α-amino acids, their salts and esters, such as N-phenylglycine, salts of N-phenylglycine, and alkyl esters of N-phenylglycine such as N-phenylglycine ethyl ester and N-phenylglycine benzyl ester. More preferred hydrogen donors are 2-mercaptobenzoxazole, 2-mercaptobenzothiazole, 2-mercaptobenzimidazole, 3-mercapto-1,2,4-triazole, N-phenylglycine, N-phenylglycine ethyl ester, and N-phenylglycine benzyl ester. Combination of at least one mercapto compound and at least one N-aryl-α-amino acid or its ester or salt can be advantageously used in the photosensitive layer to increase the photospeed. The hydrogen donor is added in the photosensitive layer preferably at 0.01 to 15% by weight of the photosensitive layer, more preferably 0.1 to 10%, and most preferably 0.5 to 5%.

Various surfactants can be added into the photosensitive layer to allow or enhance the on-press developability with ink and/or fountain. Both polymeric and small molecule surfactants can be used. However, it is preferred that the surfactant has low or no volatility so that it will not evaporate from the photosensitive layer of the plate during storage and handling. Nonionic surfactants are preferred. Preferred nonionic surfactants are polymers and oligomers containing one or more polyether (such as polyethylene glycol, polypropylene glycol, and copolymer of ethylene glycol and propylene glycol) segments. Examples of preferred nonionic surfactants are block copolymers of propylene glycol and ethylene glycol (also called block copolymer of propylene oxide and ethylene oxide); ethoxylated or propoxylated acrylate oligomers; and polyethoxylated alkylphenols and polyethoxylated fatty alcohols. The nonionic surfactant is preferably added at from 0.1 to 30% by weight of the photosensitive layer, more preferably from 0.5 to 20%, and most preferably from 1 to 15%.

A hydrophilic or oleophilic micro particles can be added into the photosensitive layer to enhance, for example, the developability and non-tackiness of the plate. Suitable micro particles include polymer particles, talc, titanium dioxide, barium sulfate, silicone oxide, fumed silica, and aluminum micro particles, with an average particle size of less than 10 microns, preferably less than 5 microns, more preferably less than 2 microns, and most preferably less than 1 microns. A suitable particular dispersion is described in U.S. Pat. No. 6,071,675, the entire disclosure of which is hereby incorporated by reference.

For plates with rough and/or porous surface, a thin releasable interlayer can be deposited between the substrate and the photosensitive layer. Preferably, the substrate surface is rough and/or porous enough and the interlayer is thin enough to allow bonding between the photosensitive layer and the substrate through mechanical interlocking. Such a plate configuration is described in U.S. Pat. No. 6.014,929, the entire disclosure of which is hereby incorporated by reference. Preferred releasable interlayer comprises a water-soluble polymer. Polyvinyl alcohol (including various water-soluble derivatives of polyvinyl alcohol) is the preferred water-soluble polymer. Usually pure water-soluble polymer is coated. However, one or more surfactant and other additives may be added. The water-soluble polymer is generally coated from an aqueous solution with water as the only solvent. A water-soluble organic solvent, preferably an alcohol such as ethanol or isopropanol, can be added into the water-soluble polymer aqueous coating solution to improve the coatability. The alcohol is preferably added at less than 40% by weight of the solution, more preferably at less than 20%, and most preferably at less than 10%. The releasable interlayer preferably has an average coverage of 1 to 200 mg/m², more preferably 2 to 100 mg/m², and most preferably 4 to 40 mg/m². The substrate preferably has an average surface roughness Ra of 0.2 to 2.0 microns, and more preferably 0.4 to 1.0 microns.

The photosensitive layer can be conformally coated onto a roughened substrate (for example, with Ra of larger than 0.4 microns) at thin coverage (for example, of less than 1.2 g/m²) so that the plate can have microscopic peaks and valleys on the photosensitive layer coated surface and exhibit low tackiness and good block resistance, as described in U.S. Pat. No. 6,242,156, the entire disclosure of which is hereby incorporated by reference.

An ink and/or fountain solution soluble or dispersible overcoat can be coated on the photosensitive layer for the plate of this invention to, for example, improve the photospeed, surface durability, and/or on-press developability. Particularly preferred overcoat is a water soluble or dispersible overcoat. The overcoat preferably comprises a water-soluble polymer, such as polyvinyl alcohol (including various water-soluble derivatives of polyvinyl alcohol). Combination of two or more water-soluble polymers (such as a combination of polyvinyl alcohol and polyvinylpyrrolidone) can also be used. Polyvinyl alcohol is a preferred water-soluble polymer. Various additives, such as surfactant, wetting agent, defoamer, leveling agent and dispersing agent, can be added into the overcoat formulation to facilitate, for example, the coating or development process. Examples of surfactants useful in the overcoat of this invention include polyethylene glycol, polypropylene glycol, and copolymer of ethylene glycol and propylene glycol, polysiloxane surfactants, perfluorocarbon surfactants, alkylphenyl ethylene oxide condensate, sodium dioctylsulfosuccinate, sodium dodecylbenzenesulfonate, and ammonium laurylsulfate. Various organic or inorganic emulsion or dispersion may be added into the overcoat to, for example, reduce the tackiness or moisture sensitivity of the plate. The overcoat preferably has a coverage of from 0.001 to 3.0 g/m², more preferably from 0.005 to 1.0 g/m², and most preferably from 0.01 to 0.15 g/m².

A preferred thermosensitive lithographic plate of this invention comprises on a substrate a thermosensitive layer comprising a polymeric binder (with or without ethylenic groups), a free radical polymerizable monomer having at least one terminal ethylenic group, a free-radical initiator, and an infrared absorbing dye. A nonionic surfactant is preferably added in the thermosensitive layer. Other additives such as surfactant, dye or pigment, exposure-indicating dye (such as leuco crystal violet, leucomalachite green, azobenzene, 4-phenylazodiphenylamine, and methylene blue dyes). and free-radical stabilizer (such as methoxyhydroquinone) may be added. The monomer preferably has at least 3 (meth)acrylate groups, more preferably at least 4 (meth)acrylate groups, even more preferably at least 5 (meth)acrylate groups, and most preferably at least 6 (meth)acrylate groups. The monomer can be a urethane (meth)acrylate monomer or a non-urethane (meth)acrylate monomer; preferably the monomer is a urethane (meth)actylate monomer; more preferably both a non-urethane (meth)acrylate monomer and a urethane (meth)acrylate monomer are used in the photosensitive layer. One or more other monomers can be added in the photosensitive layer. The weight ratio of all the monomers to all the polymeric binders is preferably larger than 0.5, more preferably larger than 1.0, even more preferably larger than 1.5, and most preferably larger than 2.0. An ink and/or fountain solution soluble or dispersible overcoat is preferably coated on the photosensitive layer.

Another preferred thermosensitive lithographic plate of this invention comprises on a substrate a thermosensitive layer comprising a polymeric binder, a urethane monomer having at least 3 (meth)acrylate groups, a non-urethane monomer having at least 3 (meth)acrylate groups, a free-radical initiator, and an infrared absorbing dye. Preferably, the urethane monomer has at least 4 (meth)acrylate groups, and the non-urethane monomer has at least 4 (meth)acrylate groups. More preferably, the urethane monomer has at least 6 (meth)acrylate groups. A nonionic surfactant is preferably added. One or more other monomers can be added in the photosensitive layer. The weight ratio of all the urethane (meth)acrylate monomer to all the non-urethane (meth)acrylate monomer is preferably from 0.10 to 10.0, more preferably 0.30 to 1.0. An ink and/or fountain solution soluble or dispersible overcoat is preferably coated on the photosensitive layer.

A third preferred thermosensitive lithographic plate of this invention comprises on a substrate a thermosensitive layer comprising an epoxy or vinyl ether monomer having at least one epoxy or vinyl ether group, a Bronsted acid generator capable of generating free acid in the presence of an infrared absorbing dye or pigment upon exposure to an infrared radiation, and an infrared absorbing dye or pigment (preferably infrared absorbing dye). A polymeric binder is preferably added. Other additives such as surfactant, dye or pigment, exposure-indicating dye, and acid quencher (usually an alkaline compound, such as tetrabutylammonium hydroxide or triethylamine) may be added.

A fourth preferred thermosensitive lithographic plate of this invention comprises on a substrate a thermosensitive layer comprising a polymeric binder and an infrared absorbing dye or pigment (preferably infrared absorbing dye); said thermosensitive layer is developable with ink and/or fountain solution and capable of hardening through crosslinking of the polymeric binder upon exposure to an infrared laser. A nonionic surfactant and/or a water-soluble polymer are preferably added in the thermosensitive layer. Other additives such as other surfactant, dye or pigment, and exposure indicating dye can also be added.

A fifth preferred thermosensitive lithographic plate of this invention comprises on a substrate a thermosensitive layer comprising a polymeric particles and an infrared absorbing dye or pigment (preferably infrared absorbing dye); said thermosensitive layer is developable with ink and/or fountain solution and capable of hardening through coalescence of the polymer particles upon exposure to an infrared laser. A nonionic surfactant and/or a water-soluble polymer are preferably added in the thermosensitive layer. Other additives such as other surfactant, dye or pigment, and exposure indicating dye can also be added.

A preferred visible or ultraviolet light sensitive lithographic printing plate of this invention comprises on a substrate a photosensitive layer comprising a polymeric binder (with or without ethylenic groups), a free radical polymerizable monomer having at least one terminal ethylenic group, a free-radical initiator, and a visible or ultraviolet sensitizing dye. A nonionic surfactant is preferably added in the photosensitive layer. Other additives such as surfactant, dye or pigment, exposure-indicating dye, and free-radical stabilizer may be added. The monomer preferably has at least 3 (meth)acrylate groups, more preferably at least 4 (meth)acrylate groups, even more preferably at least 5 (meth)acrylate groups, and most preferably at least 6 (meth)acrylate groups. The monomer can be a urethane (meth)acrylate monomer or a non-urethane (meth)acrylate monomer; preferably the monomer is a urethane (meth)actylate monomer; more preferably both a non-urethane (meth)acrylate monomer and a urethane (meth)acrylate monomer are used in the photosensitive layer. One or more other monomers can be added in the photosensitive layer. The weight ratio of all the monomers to all the polymeric binders is preferably larger than 0.5, more preferably larger than 1.0, even more preferably larger than 1.5, and most preferably larger than 2.0. An ink and/or fountain solution soluble or dispersible overcoat is preferably coated on the photosensitive layer.

Another preferred visible or ultraviolet light sensitive lithographic plate of this invention comprises on a substrate a photosensitive layer comprising a polymeric binder, a urethane monomer having at least 3 (meth)acrylate groups, a non-urethane monomer having at least 3 (meth)acrylate groups, a free-radical initiator, and a visible or ultraviolet sensitizing dye. Preferably, the urethane monomer has at least 4 (meth)acrylate groups, and the non-urethane monomer has at least 4 (meth)acrylate groups. More preferably, the urethane monomer has at least 6 (meth)acrylate groups. A nonionic surfactant is preferably added. One or more other monomers can be added in the photosensitive layer. The weight ratio of all the urethane (meth)acrylate monomer to all the non-urethane (meth)acrylate monomer is preferably from 0.10 to 10.0, more preferably 0.30 to 1.0. An ink and/or fountain solution soluble or dispersible overcoat is preferably coated on the photosensitive layer.

A preferred violet or ultraviolet light sensitive lithographic plate of this invention comprises on a substrate a photosensitive layer comprising a polymeric binder, a free radical polymerizable monomer having at least one terminal ethylenic group, a free-radical initiator, and a violet or ultraviolet sensitizing dye. A hydrogen donor is preferably added to increase the photospeed. A nonionic surfactant is preferably added to enhance on-press developability. Other additives such as surfactant, dye or pigment, exposure-indicating dye, and free-radical stabilizer may be added. The monomer preferably has at least 3 (meth)acrylate groups, more preferably at least 4 (meth)acrylate groups, even more preferably at least 5 (meth)acrylate groups, and most preferably at least 6 (meth)acrylate groups. The monomer can be a urethane (meth)acrylate monomer or a non-urethane (meth)acrylate monomer; preferably the monomer is a urethane (meth)actylate monomer; more preferably both a non-urethane (meth)acrylate monomer and a urethane (meth)acrylate monomer are used in the photosensitive layer. One or more other monomers can be added in the photosensitive layer. The weight ratio of all the monomers to all the polymeric binders is preferably larger than 0.5, more preferably larger than 1.0, even more preferably larger than 1.5, and most preferably larger than 2.0. An ink and/or fountain solution soluble or dispersible overcoat is preferably coated on the photosensitive layer.

Another preferred violet or ultraviolet laser sensitive lithographic plate of this invention comprises on a substrate a photosensitive layer comprising a polymeric binder, a monomer having at least 3 (meth)acrylate group, a hexaarylbiimidazole or titanocene compound, a dialkylaminobenzophenone compound, and a hydrogen donor. A hexaarylbiimidazole compound is preferred among hexaarylbiimidazole and titanocene compounds. A preferred dialkylaminobenzophenone compound is a 4,4′-bis(dialkylamino)benzophenone compound. Said monomer is preferably a urethane (meth)acrylate monomer. More preferably, said monomer is a urethane (meth)acrylate monomer and said photosensitive layer further comprises a non-urethane (meth)acrylate monomer. Even more preferably, said photosensitive layer comprises a urethane monomer with at least 3 (meth)acrylate groups and a non-urethane monomer with at least 3 (meth)acrylate groups. Most preferably, said photosensitive layer comprises a urethane monomer with at least 4 (meth)acrylate groups and a non-urethane monomer with at least 4 (meth)acrylate groups. A nonionic surfactant is preferably added in the photosensitive layer. The weight ratio of all the monomers to all the polymeric binders is preferably larger than 0.5, more preferably larger than 1.0, even more preferably larger than 1.5, and most preferably larger than 2.0. An ink and/or fountain solution soluble or dispersible overcoat is preferably coated on the photosensitive layer.

As for all the photosensitive layer of this invention, the above photosensitive layers (including thermosensitive layers) are soluble or dispersible in ink and/or fountain solution, so that they can be on-press developed with ink and/or fountain solution.

On-press developable lithographic plates and photosensitive layers as described in U.S. Pat. Nos. 6,482,571, 6,576,401, 5,548,222, 6,541,183, 6,551,757, 6,899,994 and 6,949,327, and U.S. patent application Ser. No. 11/057,663, Ser. No. 11/175,518, Ser. No. 11/266,817, Ser. No. 11/336,132, Ser. No. 11,356,911, and Ser. No. 11/599,734, the entire disclosures of which are hereby incorporated by reference, can be used for the instant invention.

The hardened areas of the photosensitive layer should exhibit an affinity or aversion substantially opposite to the affinity or aversion of the substrate to at least one printing liquid selected from the group consisting of ink and an abhesive fluid for ink. For example, a wet plate can have a hydrophilic substrate and an oleophilic photosensitive layer, or can have an oleophilic substrate and a hydrophilic photosensitive layer; a waterless plate can have an oleophilic substrate and an oleophobic photosensitive layer, or can have an oleophobic substrate and an oleophilic photosensitive layer. An abhesive fluid for ink is a fluid that repels ink. Fountain solution is the most commonly used abhesive fluid for ink. A wet plate is printed on a wet press equipped with both ink and fountain solution, while a waterless plate is printed on a waterless press equipped with ink.

Usually, as for most printing plates described in the literature, the photosensitive layer exhibits an affinity or aversion substantially opposite to the affinity or aversion of the substrate to at least one printing liquid selected from the group consisting of ink and an abhesive fluid for ink, and does not switch its affinity or aversion upon laser exposure. However, certain photosensitive layer exhibits substantially the same affinity or aversion as the substrate and is capable of switching to opposite affinity or aversion upon exposure to a laser (with or without further treatment such as on-press development with ink and/or fountain solution), as described in U.S. Pat. Nos. 6,331,375, 5,910,395, 6,720,464, and 6,136,503. Both non-phase-switchable photosensitive layer and phase-switchable photosensitive layer can be used for the current invention. Preferred is a non-phase-switchable photosensitive layer (coated on a substrate with opposite affinity or aversion). More preferred is an oleophilic photosensitive layer (coated on a hydrophilic substrate).

Infrared lasers useful for the imagewise exposure of the thermosensitive plates of this invention include laser sources emitting in the near infrared region, i.e. emitting in the wavelength range of from 750 to 1200 nm, and preferably from 800 to 1100 nm. Particularly preferred infrared laser sources are laser diodes emitting around 830 nm or a NdYAG laser emitting around 1060 nm. The plate is exposed at a laser dosage that is sufficient to cause hardening in the exposed areas but not high enough to cause substantial thermal ablation. The exposure dosage is preferably from 1 to 2000 mJ/cm², more preferably from 5 to 500 mJ/cm², and most preferably from 20 to 200 mJ/cm², depending on the sensitivity of the thermosensitive layer.

Visible lasers (including violet laser) useful for the imagewise exposure of the visible light sensitive plates of this invention include any laser emitting in the wavelength range of from 390 to 600 nm. Examples of suitable visible lasers include frequency-doubled Nd/YAG laser (about 532 nm), argon ion laser (about 488 nm), violet diode laser (about 405 nm), and visible LEDs. Violet laser diode is especially useful because of its small size and relatively low cost. The exposure dosage is preferably from 1 to 2000 μJ/cm² (0.001 to 2 mJ/cm²), more preferably from 5 to 500 μJ/cm², and most preferably from 20 to 200 μJ/cm², depending on the sensitivity of the photosensitive layer.

Violet or ultraviolet lasers useful for the imagewise exposure of the plates of this invention include any lasers having a wavelength of from 200 to 430 nm, such as violet laser diodes having a wavelength of from 390 to 430 nm, and ultraviolet laser diodes or LEDs having a wavelength of from 200 to 390 nm. Laser diodes are preferred violet or ultraviolet lasers. The exposure dosage is preferably from 1 to 2000 μJ/cm² (0.001 to 2 mJ/cm²), more preferably from 5 to 500 μJ/cm², and most preferably from 20 to 200 μJ/cm², depending on the sensitivity of the photosensitive layer.

The plate mounted on a lithographic press is exposed with the lasers developed with ink and/or fountain solution, and then prints out regular printed sheets; the plate mounted on the plate cylinder is covered by the press covers to block off at least 90% (preferably at least 99%, more preferably at least 99.8%, and most preferably all) of the room light or of the unsafe portion of the room light during the exposure and on-press development. The ink and/or fountain solution solubilized or dispersed photosensitive layer (and overcoat, if any) can be mixed into the ink and/or the fountain solution on the rollers, and/or can be transferred to the blanket and then the receiving medium (such as paper). The fountain solution roller is engaged (to the plate cylinder as for conventional inking system or to the ink roller as for integrated inking system) for preferably 0 to 100 rotations, more preferably 1 to 50 rotations and most preferably 5 to 20 rotations (of the plate cylinder), and the ink roller is then engaged to the plate cylinder for preferably 0 to 100 rotations, more preferably 1 to 50 rotations and most preferably 5 to 20 rotations before engaging the plate cylinder and feeding the receiving medium. Good quality prints should be obtained preferably under 40 initial impressions, more preferably under 20 impressions, and most preferably under 5 impressions.

For conventional wet press, usually fountain solution is applied (to contact the plate) first, followed by contacting with ink roller. For press with integrated inking/dampening system, the ink and fountain solution are emulsified by various press rollers before being transferred to the plate as emulsion of ink and fountain solution. However, in this invention, the ink and fountain solution may be applied at any combination or sequence, as needed for the plate. There is no particular limitation. The recently introduced single fluid ink that can be used for printing wet lithographic plate without the use of fountain solution, as described in for example U.S. Pat. No. 6,140,392, can also be used for the on-press development and printing of the plate of this invention.

The ink used in this application can be any ink suitable for lithographic printing. Most commonly used lithographic inks include “oil based ink” which crosslinks upon exposure to the oxygen in the air and “rubber based ink” which does not crosslink upon exposure to the air. Specialty inks include, for example, radiation-curable ink and thermally curable ink. An ink is an oleophilic, liquid or viscous material which generally comprises a pigment dispersed in a vehicle, such as vegetable oils, animal oils, mineral oils, and synthetic resins. Various additives, such as plasticizer, surfactant, drier, drying retarder, crosslinker, and solvent may be added to achieve certain desired performance. The compositions of typical lithographic inks are described in “The Manual of Lithography” by Vicary, Charles Scribner's Sons, New York, and Chapter 8 of “The Radiation Curing: Science and Technology” by Pappas, Plenum Press, New York, 1992.

The fountain solution used in this application can be any fountain solution used in lithographic printing. Fountain solution is used in the wet lithographic printing press to dampen the hydrophilic areas (non-image areas), repelling ink (which is hydrophobic) from these areas. Fountain solution contains mainly water, generally with addition of certain additives such as gum arabic and surfactant. Small amount of alcohol such as isopropanol can also be added in the fountain solution. Water is the simplest type of fountain solution. Fountain solution is usually neutral to mildly acidic. However, for certain plates, mildly basic fountain solution is used. The type of fountain solution used depends on the type of plate substrate as well as the photosensitive layer. Various fountain solution compositions are described in U.S. Pat. Nos. 4,030,417 and 4,764,213.

This invention is further illustrated by the following non-limiting examples of its practice.

### EXAMPLES 1-5

This example demonstrates the importance of imaging and on-press developing a high-speed laser sensitive plate in the dark or under safe light.

An electrochemically roughened, anodized, and polyvinylphosphonic acid treated aluminum sheet was first coated with a 0.1% aqueous solution of polyvinyl alcohol (Celvol 540, from Celanese) with a #6 Meyer rod, followed by drying in an oven at 100° C. for 2 min. The polyvinyl alcohol coated substrate was further coated with the photosensitive layer formulation PS-1 with a #8 Meyer rod, followed by drying in an oven at 90° C. for 2 min.

### PS-1

| Component | Weight ratios |
|---|---|
| Neocryl B-728 (Polymer from Zeneca) | 3.193 |
| Sartomer SR-399 (Acrylic monomer from Sartomer) | 7.630 |
| Pluronic L43 (Nonionic surfactant from BASF) | 0.649 |
| 2,2-Bis(2-chlorophenyl)-4,4′,5,5′- | 1.407 |
| tetraphenyl-1,1′-biimidazole | |
| 2-Mercaptobenzoxazole | 0.839 |
| 4,4′-Bis(diethylamino)benzophenone | 0.281 |
| 2-Butanone | 86.000 |

The photosensitive layer coated plate was further coated with a water-soluble overcoat OC-1 using a #6 Meyer rod, followed b) drying in an oven at 100° C. for 2 min.

### OC-1

| Component | Weight ratios |
|---|---|
| Airvol 205 (polyvinyl alcohol from Air Products) | 0.40 |
| Diocryl sulfosuccinate sodium salt (surfactant) | 0.02 |
| Water | 99.58 |

The plate was exposed with a violet plate imager equipped with a 30 mw violet laser diode emitting at about 405 nm (MAKO-4 from ECRM) for a dosage of about 60 μJ/cm². The plate was imaged in a dim red light room, and was kept in a light tight box before and after imaging.

The laser exposed plate was cut into five pieces, and each piece was wrapped with a separate aluminum foil. Each piece of the plate was tested on press under a different lighting condition. The first piece was tested in the dark (with all lights turned off). The second piece was tested under a 60-watt yellow light (yellow coated incandescence light, from General Electric). The third piece was tested under a 60-watt red light (red coated incandescence light, from General Electric). The fourth piece was tested under a 20-watt white office fluorescence light (from General Electric). The fifth piece was tested under a 100-watt regular incandescence light (for home use, from General Electric). Each light was about 2 meters from the top of the press. It took about 5 minutes to mount each plate and start up the press.

Each of the exposed plate pieces was unwrapped and tested on a wet lithographic press (AB Dick 360) under the above described lighting condition (including dark). The plate was directly mounted on the plate cylinder of the press. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper. The printed sheets were evaluated for the on-press developability of the plates, with the results summarized in Table 1.

TABLE 1

| | Background | Background | Inking in |
|---|---|---|---|
| | at 20 | at 200 | imaging |
| Press room lighting | impressions | impressions | areas |
| In darkness (no light) | Clean | Clean | Good |
| Yellow light | Clean | Clean | Good |
| Red light | Clean | Clean | Good |
| White fluorescence light | Inked | Heavy toning | Good |
| Regular incandescence light | Inked | Heavy toning | Good |

### EXAMPLES 6-10

An electrochemically roughened, anodized, and silicate treated aluminum sheet was coated with thermosensitive layer formulation PS-2 using a #8 Meyer rod, followed by drying in an oven at 90° C. for 2 min.

### PS-2

| Component | Weight ratios |
|---|---|
| Neocryl B-728 (Polymer from Zeneca) | 2.73 |
| Sartomer SR-399 (Acrylic monomer from Sartomer) | 6.52 |
| Pluronic L43 (Nonionic surfactant from BASF) | 0.56 |
| 2,4-Bis(trichloromethyl)-6-[(4-ethoxyethylenoxy)- | 1.00 |
| phen-1-yl]-s-triazine | |
| ADS-830AT (Infrared absorbing cyanine dye from | 0.10 |
| American Dye Source) | |
| Acetone | 90.0 |

The thermosensitive layer coated plate was further coated with a water-soluble overcoat OC-2 using a #6 Meyer rod, followed by drying in an oven at 100° C. for 2 min.

### OC-2

| Component | Weight ratios |
|---|---|
| Airvol 205 (Polyvinyl alcohol from Air Products) | 5.00 |
| Zonyl FSO (Perfluorinated surfactant from DuPont) | 0.02 |
| Water | 95.00 |

The plate was exposed with an infrared laser plate imager equipped with laser diodes emitting at about 830 nm (Trendsetter from Creo) at a dosage of 150 mJ/cm². The plate was imaged in a dim red light room, and was kept in a light tight box before and after imaging.

The laser exposed plate was cut into five pieces, and kept in a light-tight box for all the time except for the specific exposure as indicated. The first piece was kept in the dark (in a box) all the time after exposure. The second piece was exposed to a 60-watt yellow light (yellow coated incandescence light, from General Electric) at a distance of 2 meters for 60 minutes. The third piece was exposed to a 60-watt red light (red coated incandescence light, from General Electric) at a distance of 2 meters for 60 minutes. The fourth piece was exposed to a 40-watt white office fluorescence light (from General Electric) at a distance of 2 meters for 60 minutes. The fifth piece was exposed to a 100-watt regular incandescence light (for home use, from General Electric) at a distance of 2 meters for 60 minutes.

The exposed plate pieces as treated above were tested on a wet lithographic press (AB Dick 360) under a dim red light. The plate was directly mounted on the plate cylinder of the press. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper. The printed sheets were evaluated for the on-press developability of the plates, with the results summarized in Table 2.

TABLE 2

| | Background | Background | Inking in |
|---|---|---|---|
| Room light exposure before | at 20 | at 200 | imaging |
| mounting on press | impressions | impressions | areas |
| In darkness (no exposure) | Clean | Clean | Good |
| Yellow light for 60 minutes | Clean | Clean | Good |
| Red light for 60 minutes | Clean | Clean | Good |
| White office fluorescence | Inked | Heavy toning | Good |
| light for 60 mintues | | | |
| Regular incandescence light | Inked | Heavy toning | Good |
| for 60 minutes | | | |

I claim:

1. A lithographic printing press comprising:
(a) a plate cylinder mounted with a lithographic printing plate comprising on a substrate a photosensitive layer soluble or dispersible in ink and/or fountain solution and capable of hardening upon exposure to a laser having a wavelength selected from 200 to 1200 nm;
(b) an exposure means capable of emitting said laser to imagewise expose said mounted plate; and
(c) an inking means comprising an inking unit or both an inking unit and a fountain unit;
(d) wherein said press is in a pressroom having white room light; and at least said plate mounted on the plate cylinder is within a compartment shielded with covers and other press parts so that, when the covers are fully closed and when there is no light source turned on within said compartment, the intensity of the light at each wavelength below 450 nm around the plate cylinder is less than 10% of the intensity of the room light around the outer top surface of the press at such wavelength.

2. The lithographic press of claim 1 wherein, when the covers are fully closed and when there is no light source turned on within said compartment, the intensity of the light at each wavelength below 450 nm around the plate cylinder is less than 1% of the intensity of the room light at such wavelength around the outer top surface of the press.

3. The lithographic press of claim 1 wherein, when the covers are fully closed and when there is no light source turned on within said compartment, the intensity of the light at each wavelength below 450 nm around the plate cylinder is less than 0.2% of the intensity of the room light at such wavelength around the outer top surface of the press.

4. The lithographic press of claim 1 wherein, when the covers are fully closed and when there is no light source turned on within said compartment, the intensity of the light at any wavelength around the plate cylinder is less than 1% of the intensity of the room light at such wavelength around the outer top surface of the press.

5. The lithographic press of claim 1 wherein, when the covers are fully closed and when there is no light source turned on within said compartment, the compartment is in darkness or substantial darkness.

6. The lithographic press of claim 1 wherein said covers include certain areas which are non-transparent to any white light and other areas which are only transparent to a yellow or red light; and, when the covers are fully closed and when there is no light source turned on within said compartment, the compartment is in a yellow or red lighting.

7. The lithographic press of claim 1 wherein said compartment further includes a yellow or red light source which can be turned on or off.

8. The lithographic press of claim 1 wherein said compartment does not contain any light source.

9. The lithographic press of claim 1 further comprising a light-tight cassette containing at least one lithographic plate for automatically loading the lithographic plate onto the plate cylinder.

10. The lithographic press of claim 1 wherein the lithographic plate is in the form of continuous web with one end rolled out from a fresh roll of plate in a light-light cartridge and the other end rolled into a used roll in a second cartridge, both cartridges are installed within the plate cylinder with the portion of the plate between the cartridges being mounted on the plate cylinder, and said plate is capable of unwinding from the light-tight cartridge and winding into the second cartridge at the beginning of a printing operation.

11. The lithographic press of claim 10 wherein said plate cylinder is mounted with 2 sets of plates, the first plate is mounted on the plate cylinder surface from about 0° to about 180° of the rotating direction of the cylinder with the corresponding fresh and used plate rolls installed within the cylinder, and the second plate is mounted on the same plate cylinder surface from about 180° to about 360° (0°) of the rotating direction of the cylinder with the corresponding fresh and used plate rolls installed within the cylinder.

12. The lithographic press of claim 10 wherein said plate cylinder is mounted with 4 sets of plates, the first plate is mounted on the plate cylinder surface from about 0° to about 90° of the rotating direction of the cylinder with the corresponding fresh and used plate rolls installed within the cylinder, the second plate is mounted on the plate cylinder surface from about 90° to about 180° of the rotating direction of the cylinder with the corresponding fresh and used rolls installed within the cylinder, the third plate is mounted on the plate cylinder surface from about 180° to about 270° of the rotating direction of the cylinder with the corresponding fresh and used rolls installed within the cylinder, and the fourth plate is mounted on the plate cylinder surface from about 270° to about 360° (0°) of the rotating direction of the cylinder with the corresponding fresh and used rolls installed within the cylinder.

13. A method of lithographically printing images on a receiving medium, comprising in order:
(a) providing a lithographic printing press comprising (i) a plate cylinder, (ii) an exposure means capable of emitting a laser having a wavelength selected from 200 to 1200 nm, and (iii) an inking means comprising an inking unit or both an inking unit and a fountain unit;
(b) mounting onto said plate cylinder a lithographic printing plate comprising on a substrate a photosensitive layer soluble or dispersible in ink and/or fountain solution and capable of hardening upon exposure to said laser;
(c) imagewise exposing said plate with said laser to cause hardening of the photosensitive layer in the exposed areas;
(d) applying ink and/or fountain solution from said inking means to said plate to remove the non-hardened areas of said photosensitive layer; and
(e) lithographically printing images from said plate to the receiving medium;
(f) wherein said press is in a pressroom having white room light; and at least said plate mounted on the plate cylinder is within a compartment shielded with covers and other press parts so that, when the covers are fully closed and when there is no light source turned on within said compartment, the intensity of the light at each wavelength below 450 nm around the plate cylinder is less than 10% of the intensity of the room light around the outer top surface of the press at such wavelength; and said covers are fully closed during at least a portion of said steps (c) and (d).

14. The method of claim 13 wherein, when the covers are fully closed and when there is no light source turned on within said compartment, the intensity of the light at each wavelength below 450 nm around the plate cylinder is less than 1% of the intensity of the room light at such wavelength around the outer top surface of the press.

15. The method of claim 13 wherein, when the covers are fully closed and when there is no light source turned on within said compartment, the intensity of the light at any wavelength around the plate cylinder is less than 1% of the intensity of the room light at such wavelength around the outer top surface of the press.

16. The method of claim 13 wherein, when the covers are fully closed and when there is no light source turned on within said compartment, the intensity of the light at any wavelength around the plate cylinder is less than 0.2% of the intensity of the room light at such wavelength around the outer top surface of the press.

17. The method of claim 13 wherein, when the covers are fully closed and when there is no light source turned on within said compartment, the compartment is in darkness or substantial darkness.

18. The method of claim 13 wherein said laser is a violet or ultraviolet laser with a wavelength of from 200 to 430 nm and is exposed at a dosage of less than 500 μJ/cm² (0.5 mJ/cm²).

19. The method of claim 13 wherein said laser is an infrared laser with a wavelength of from 750 to 1200 nm and is exposed at a dosage of less than 500 mJ/cm².

20. The method of claim 13 wherein said covers include certain areas which are non-transparent to any white light and other areas which are only transparent to a yellow or red light.

21. The method of claim 13 wherein said covers include certain areas which are only transparent to a yellow or red light to allow viewing of the plate mounted on the plate cylinder, and said press contains a yellow or red light source within said compartment, and said yellow or red light source is turned on during at least a portion of said steps (b)-(d).

22. The method of claim 13 wherein said covers are fully closed in steps (b) to (d), and at least a portion of said covers is opened in all or part of the duration of step (e).

23. The method of claim 13 wherein said photosensitive layer comprises a polymeric binder, a polymerizable monomer, an initiator, and a sensitizing dye; and is capable of hardening through polymerization upon exposure with said laser.

24. The method of claim 13 wherein said photosensitive layer comprises a polymeric binder and a sensitizing dye or pigment, and is capable of hardening through chemical reaction and/or physical change upon exposure with said laser.

25. The method of claim 13 wherein said lithographic plate further comprises an ink and/or fountain solution soluble or dispersible overcoat on said photosensitive layer.

26. The method of claim 13 wherein said lithographic plate is automatically mounted onto the plate cylinder from a light-tight cassette containing at least one lithographic plate.

27. The method of claim 13 wherein said lithographic plate is in the form of continuous web with one end rolled out from a fresh roll of plate in a light-light cartridge and the other end rolled into a used roll in a second cartridge, both cartridges are installed within the plate cylinder with the portion of the plate between the cartridges being mounted on the plate cylinder, and said plate is unwound from the light-tight cartridge and wound into the second cartridge in order to mount a fresh portion to replace a used portion of the plate on the plate cylinder at the beginning of a new printing operation (step b).

28. A method of lithographically printing images on a receiving medium, comprising in order:
(a) providing a lithographic printing press comprising (i) a plate cylinder, (ii) an exposure means capable of emitting a laser having a wavelength selected from 200 to 1200 nm, and (iii) an inking means comprising an inking unit and a fountain unit;
(b) mounting from a light-tight cassette onto said plate cylinder a lithographic printing plate comprising on a hydrophilic substrate an oleophilic photosensitive layer soluble or dispersible in ink and/or fountain solution and capable of hardening upon exposure to said laser;
(c) imagewise exposing said plate with said laser to cause hardening of the photosensitive layer in the exposed areas;
(d) applying ink and fountain solution from said inking means to said plate to remove the non-hardened areas of said photosensitive layer; and
(e) lithographically printing images from said plate to the receiving medium;
(f) wherein said press is in a pressroom having white room light; and at least said plate mounted on the plate cylinder is within a compartment shielded with covers and other press parts so that, when the covers are fully closed, the intensity of the light at each wavelength below 450 nm around the plate cylinder is less than 1% of the intensity of the room light around the outer top surface of the press at such wavelength; and said covers are fully closed during substantially all of said steps (b) to (d) and are at least partially opened during substantially all of said step (e).
